(19) United States
(12) Patent Application Publication
(10) Pub. No.: US 2009/0080163 A1
(43) Pub. Date: Mar. 26, 2009

(54) PRINTED WIRING BOARD ASSEMBLY

(75) Inventor: Timothy F. Lyons, Apalachin, NY (US)

Correspondence Address: MICHAEL BEST & FRIEDRICH LLP, 100 E WISCONSIN AVENUE, Suite 3300, MILWAUKEE, WI, 53202, US

(73) Assignee: LOCKHEED MARTIN CORPORATION, Bethesda, MD (US)

(21) Appl. No.: 12/121,816

(22) Filed: May 16, 2008

Related U.S. Application Data
(60) Provisional application No. 60/930,613, filed on May 17, 2007.

(51) Int. Cl. H05K 7/00; H05K 7/20; B23Q 3/00

(52) U.S. Cl. 361/721; 361/796; 29/464

(57) ABSTRACT

A method and apparatus for aligning a connector between a printed wiring board and a mezzanine board includes mounting the printed wiring board to a frame, locating a cover with respect to the frame by way of a first pin and a second pin, fastening the cover to the frame, locating the mezzanine board with respect to the cover by way of a third pin and a fourth pin, and fastening the mezzanine board to the cover.

### RELATED APPLICATION DATA

This application claims benefit under 35 U.S.C. Section 119(e) of co-pending U.S. Provisional Application No. 60/930,613 filed May 17, 2007, which is fully incorporated herein by reference.

### GOVERNMENT LICENSE RIGHTS

The U.S. Government has a paid-up license in this invention and the right in limited circumstances to require the patent owner to license others on reasonable terms as provided for by the terms of Contract Number Q7V223 awarded by the U.S. Air Force.

### BACKGROUND

The present invention relates to printed wiring board assemblies, and more particularly, to printed wiring board assemblies having mezzanine boards.

Printed wiring board assemblies often include a main printed wiring board, sometimes referred to as a motherboard, and a mezzanine card or mezzanine board that connects to the main printed wiring board. Often, the mezzanine card connects to the main printed wiring board using pin-type connectors or plug/receptacle combinations. Each connector may have 32, 64 or more fragile plugs or pins. The mezzanine card typically provides additional functions or features for the printed wiring board assembly in addition to the functions available from the main printed wiring board. In some applications, the main printed wiring board and the mezzanine card are enclosed within a cover to protect the main printed wiring board, the mezzanine card, and electronic components coupled the mezzanine card and the main printed wiring board.

### SUMMARY

In one embodiment, the invention provides a printed wiring board assembly including a frame having a first pin-receiving aperture and a second pin-receiving aperture. A printed wiring board is mounted to the frame. A cover is coupled to the frame by at least one first fastener and has a third pin-receiving aperture and a fourth pin-receiving aperture. A first pin is positioned in the first pin-receiving aperture and the third pin-receiving aperture, and a second pin is positioned in the second pin-receiving aperture and the fourth pin-receiving aperture, to locate the cover with respect to the frame and to substantially prevent lateral movement of the of the cover with respect to the frame. A mezzanine board is mounted to the cover by at least one second fastener. The cover further includes a fifth pin-receiving aperture and a sixth pin-receiving aperture. The mezzanine board includes a seventh pin-receiving aperture and an eighth pin-receiving aperture. A third pin is positioned in the fifth pin-receiving aperture and the seventh pin-receiving aperture, and a fourth pin is positioned in the sixth pin-receiving aperture and the eighth pin-receiving aperture, to locate the mezzanine board with respect to the cover and to substantially prevent lateral movement of the mezzanine board with respect to the cover.

In another embodiment the invention provides a method of assembling a printed wiring board assembly including a printed wiring board, a frame, a cover, and a mezzanine board. The method includes mounting the printed wiring board to the frame, locating the cover with respect to the frame by way of a first pin and a second pin, fastening the cover to the frame, locating the mezzanine board with respect to the cover by way of a third pin and a fourth pin, and fastening the mezzanine board to the cover.

### BRIEF DESCRIPTION OF THE DRAWINGS

FIG. 1 is a top perspective view of a printed wiring board assembly embodying the present invention.

FIG. 2 is a cross-sectional view of the printed wiring board assembly of FIG. 1 taken along line 2-2 of FIG. 1.

FIG. 3 is an enlarged view of a portion of FIG. 2 illustrating an exemplary connector that could be used with the printed wiring board assembly of FIG. 1, with a portion removed.

FIG. 4 is a bottom side view of the printed wiring board assembly of FIG. 1.

### DETAILED DESCRIPTION

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

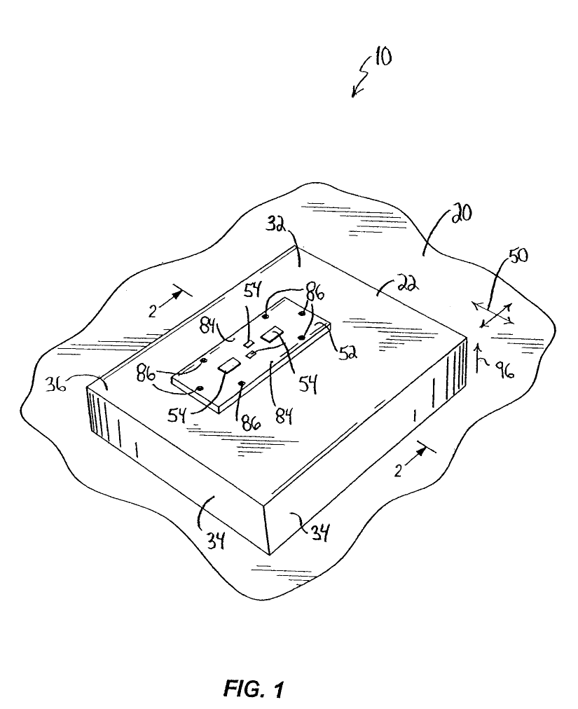

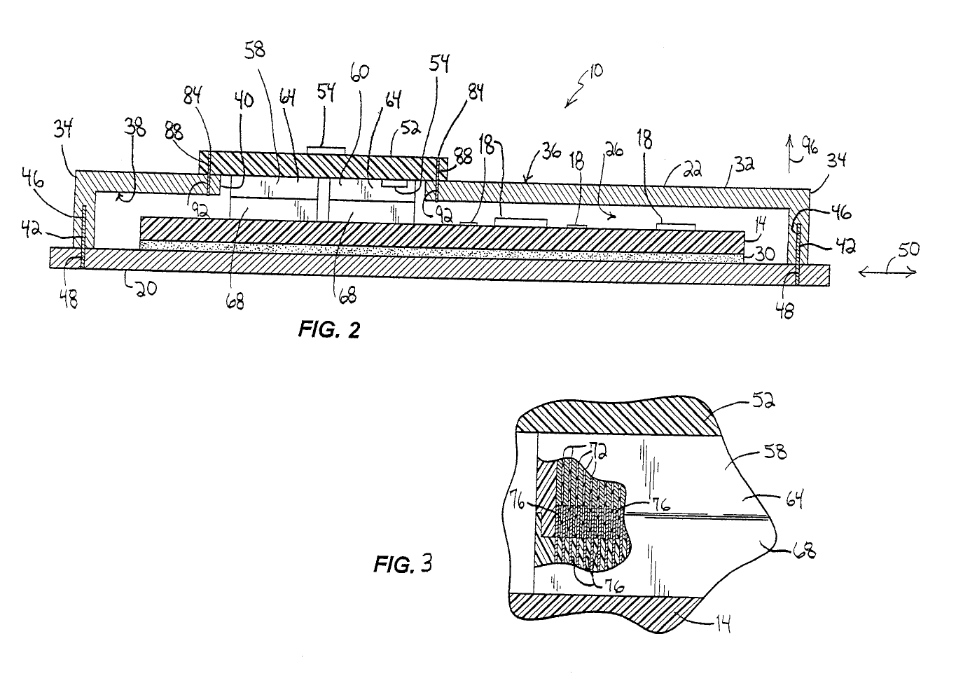

FIG. 1 illustrates a printed wiring board (PWB) assembly 10. Referring to FIG. 2, the PWB assembly 10 includes a motherboard or main PWB 14. In the illustrated construction, electronic components 18 are coupled to the main PWB 14 as is understood in the art. While the main PWB 14 has been described as a printed wiring board and the terms ‘printed wiring board’ and ‘PWB’ are used herein to describe other components of the assembly 10, it should be understood that the terms ‘printed wiring board’ and PWB can include printed circuit boards, etched wiring boards, and the like.

The PWB assembly 10 further includes a frame 20 and a cover 22 that is coupled to the frame 20 to create a cavity 26. In the illustrated construction, the main PWB 14 is bonded to the frame 20 within the cavity 26 using a bonding material 30 such as epoxy, glue, other adhesives, and the like. In one construction, the frame 20 is a cooling frame that acts as a heat sink to transfer heat away from the main PWB 14. As would be understood by one of skill in the art, the main PWB 14 can generate heat during operation. Thus, the frame 20 transfers heat away from the main PWB 14. The frame 20 and the cover 22 are preferably made from a thermally conductive material such as aluminum, steel, or another metal that acts as a heat sink, but they could also be made from plastic, ceramic, or other materials.

The cover 22 includes an upper wall 32 and sidewalls 34 that extend from the upper wall 32. The upper wall 32 includes an outer surface 36 that is located outside of the cavity 26 and an inner surface 38 that is located within the cavity 26. As best seen in FIG. 2, an aperture 40 extends through the upper wall 32 of the cover 22.

Referring to FIGS. 2 and 4, the cover 22 is coupled to the frame 20 using pins 42 and fasteners 44. The pins 42 are permanent pins in the illustrated construction. In the illustrated construction, the fasteners 44 are screws, and in other constructions, other suitable fasteners and other types of threaded fasteners can be utilized.

To assemble the cover 22 and the frame 20, each of the permanent pins 42 (two pins are used in the illustrated construction) is inserted into an aperture 46 in the cover 22 and an aperture 48 in the frame 20. The pins 42 are utilized to locate the cover 22 with respect the frame 20. A tight tolerance is maintained between the pins 42 and the apertures 46 and 48 of the cover 22 and the frame 20 such that the pins 42 hold the cover 22 from moving laterally with respect to the frame 20 or the directions of arrows 50. Then, the screws 44 are inserted into apertures in the frame 20 and the cover 22 to fasten the cover 22 to the frame 20. The pins 42 tightly maintain the relative position of the cover 22 with respect to the frame 20 as the screws 44 are inserted into the cover 22 and the frame 20. The pins 42 prevent substantial lateral movement of the cover 22 with respect to the frame 20 as the screws 44 are inserted, which can be caused by misalignments between the apertures for the screws 38 in the cover 22 and the frame 20.

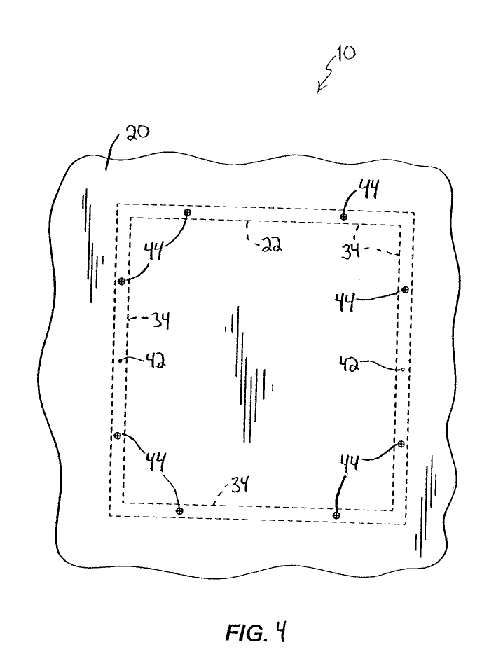

Referring to FIGS. 1 and 2, the PWB assembly 10 further includes a peripheral component interconnect mezzanine card (PMC) 52. In the illustrated construction, electronic components 54 are coupled to the PMC 52 as is understood in the art. Also, as would be understood by one of skill in the art, the PMC 52 is utilized with the main PWB 14 to provide additional functionality or features to the PWB assembly 10, such as optional features customized for a particular application. The PMC 52 is electrically coupled to the main PWB 14 using PMC connectors 58 and 60. Each of the PMC connectors 58 and 60 includes a first half 64 that is fixed to the PMC 52, and a second half 68 that is coupled to the main PWB 14. Referring to FIG. 3, in the illustrated construction, the PMC connector 64 coupled to the PMC 52 includes pins, plugs or other male-type components 72, and the PMC connector 68 coupled to the main PWB 14 includes apertures, receptacles, or other female-type components 76 that receive the male-type components 72 to electrically couple the PMC 52 and the main PWB 14. In one construction, the PMC connectors 58 and 60 are standard sixty-four pin connectors or plug/receptacle connectors, which are well known in the art. One type of plug/receptacle connector combination is the AMP Free Height Surface—Mount Connectors sold by Tyco Electronics.

In the illustrated construction, the PMC 52 is coupled to the outer surface 36 of the cover 22 such that the PMC connectors 64 of the PMC 52 extend through the aperture 40 of the cover 22. While the illustrated PMC 52 is coupled to the outer surface 36 of the cover 22, in other constructions, the PMC 52 can be coupled to the inner surface 38 of the cover 22. However, by coupling the PMC 52 to the outer surface 36 of the cover 22, and adjacent the aperture 40, electronic components 54 can be coupled to both sides of the PMC 52 as illustrated in FIG. 2.

With continued reference to FIGS. 1 and 2, the PMC 52 is coupled to the cover 22 using pins 84 and fasteners 86. In the illustrated construction, the fasteners 86 are screws. In other constructions, the fasteners 86 can be other suitable fasteners, including other types of threaded fasteners and the like. Also, in the illustrated construction, the pins 84 are tooling pins. As would be understood by one of skill in the art, tooling pins are pins having at least two pieces that can be manually separated such that the tooling pin can removably couple components. In other constructions, other types of pins, such as permanent pins and the like, can be utilized.

Referring to FIGS. 1-3, to assemble the PMC 52 to the cover 22 and the main PWB 14, the PMC connectors 64 of the PMC 52 are coupled to the PMC connectors 68 of the main PWB 14, as is understood in the art. Next, the pins 84 (two pins in the illustrated construction) are inserted through apertures 88 of the PMC 52 and into apertures 92 in the cover 22. The pins 84 are used to locate or position the PMC 52 with respect to the cover 22 and the main PWB 14. A tight tolerance is maintained between the pins 84 and the aperture 88 and 92 such that the pins 84 hold the PMC 52 from moving laterally (in the direction of arrows 50) with respect to the cover 22 and the main PWB 14. Also, because the pins 84 are tooling pins, the pins 84 also inhibit movement of the PMC 52 in the vertical direction, or in the direction of arrow 96. Then, the screws 86 are threaded through apertures in the PMC 52 and the cover 22 to fasten the PMC 52 to the cover 22. As the screws 86 are inserted into the cover 22, the pins 84 tightly maintain the relative position of the PMC 52 with respect to the cover 22 while the pins 42 tightly maintain the relative position of the cover 22 with respect to the main PWB 14. The pins 84 prevent substantial lateral movement of PMC 52 with respect to the cover 22 that can be caused by misalignments between the apertures for the screws 86. Furthermore, because the pins 84 are tooling pins, the PMC 50 is removably coupled to the cover 22 and the PMC 54 can be easily removed from the PWB assembly 10 and a different PMC, possibly having other features, can be coupled to the PWB assembly 10 as discussed above.

As would be understood by one of skill in the art, the PMC connectors 58 and 60, particularly the pins or plugs 72, can be delicate and are easily bent or broken. Therefore, it is desirable to hold the mating halves 64 and 68 of the PMC connectors 58 and 60 with respect to each other within a tight tolerance in order to protect the integrity of the mating halves 64 or plugs 72. As discussed above, the pins 84 prevent lateral movement of PMC 52 with respect to the cover 22 as the screws 86 are inserted and the pins 42 prevent lateral movement of the cover 22 with respect to the main PWB 14. Thus, the pins 84 and 42 prevent substantial relative movement between the mating halves 64 and 68 of the PMC connectors 58 and 60 during assembly.

The PWB assembly 10 can be used in any suitable application, such as avionics, marine electronics, embedded computing, rack and panel servers, and the like. In such applications, the PWB assembly 10 can be exposed to shocks, vibrations, handling or transportation, and the like. The ruggedized connection between the cover 22 and the frame 20 reduces the amount of shock, vibration, and force exposed to the PMC connectors 58 and 60. The pins 42 between the frame 20 and the cover 22 absorb shock, vibration, etc., transferred to the cover 22 and tightly hold the cover 22 from lateral movement with respect to the frame 20. Therefore, shocks, vibrations, etc., transferred to the PMC connectors 58 and 60 are minimized.

Thus, the invention provides, among other things, an improved printed wiring board assembly. Various features and advantages of the invention are set forth in the following claims.

What is claimed is:

1. A printed wiring board assembly, comprising:
a frame having a first pin-receiving aperture and a second pin-receiving aperture;
a printed wiring board mounted to the frame;
a cover coupled to the frame by at least one first fastener and having a third pin-receiving aperture and a fourth pin-receiving aperture;
a first pin positioned in the first pin-receiving aperture and the third pin-receiving aperture, and a second pin positioned in the second pin-receiving aperture and the fourth pin-receiving aperture, to locate the cover with respect to the frame; and
a mezzanine board mounted to the cover by at least one second fastener.

2. The printed wiring board assembly of claim 1, wherein the first pin and the second pin are permanent pins.

3. The printed wiring board assembly of claim 1, wherein the at least one first fastener includes a threaded fastener.

4. The printed wiring board assembly of claim 1, wherein the printed wiring board is mounted to the frame by way of a bonding material.

5. The printed wiring board assembly of claim 1, wherein the frame includes a heat sink configured to transfer heat away from the printed wiring board.

6. The printed wiring board assembly of claim 1, further comprising a mezzanine board mounted to the cover by at least one second fastener.

7. The printed wiring board assembly of claim 6, wherein the cover further includes a fifth pin-receiving aperture and a sixth pin-receiving aperture, and wherein the mezzanine board includes a seventh pin-receiving aperture and an eighth pin-receiving aperture, and wherein a third pin is positioned in the fifth pin-receiving aperture and the seventh pin-receiving aperture, and wherein a fourth pin is positioned in the sixth pin-receiving aperture and the eighth pin-receiving aperture, to locate the mezzanine board with respect to the cover.

8. The printed wiring board assembly of claim 7, wherein the cover includes a heat sink configured to transfer heat away from the mezzanine board.

9. The printed wiring board assembly of claim 7, wherein the third pin and the fourth pin are configured to substantially prevent vertical movement of the mezzanine board with respect to the cover.

10. The printed wiring board assembly of claim 7, wherein the mezzanine board is configured to be removably mounted to the cover.

11. The printed wiring board assembly of claim 7, wherein the third pin and the fourth pin are tooling pins.

12. The printed wiring board assembly of claim 1, wherein the at least one first fastener includes a threaded fastener.

13. The printed wiring board assembly of claim 12, wherein the at least one second fastener includes a threaded fastener.

14. The printed wiring board assembly of claim 6, wherein the mezzanine board includes a first connector half, and wherein the printed wiring board includes a second connector half configured to mate with the first connector half to electrically couple the mezzanine board to the printed wiring board.

15. The printed wiring board assembly of claim 14, wherein the cover includes an aperture therethrough, and wherein the cover includes a top surface and a bottom surface, and wherein the mezzanine board is mounted to the top surface of the cover, and wherein the first connector half extends through the aperture.

16. The printed wiring board assembly of claim 14, wherein one of the first connector half and the second connector half include a pin-type connector.

17. The printed wiring board assembly of claim 7, wherein the mezzanine board includes a first connector half, and wherein the printed wiring board includes a second connector half configured to mate with the first connector half to electrically connect the mezzanine board to the printed wiring board.

18. The printed wiring board assembly of claim 17, wherein the cover includes an aperture therethrough, and wherein the cover includes a top surface and a bottom surface, and wherein the mezzanine board is mounted to the top surface of the cover, and wherein the first connector half extends through the aperture.

19. The printed wiring board assembly of claim 17, wherein the first pin, the second pin, the third pin, and the fourth pin are configured to locate the first connector half with respect to the second connector half.

20. The printed wiring board assembly of claim 1, wherein the frame includes a top surface and a bottom surface, and wherein the printed wiring board is mounted to the top surface of the frame.

21. The printed wiring board assembly of claim 20, wherein the cover is coupled to the frame such that a cavity is formed between the cover and the top surface of the frame, and the printed wiring board is located in the cavity.

22. A method of assembling a printed wiring board assembly including a printed wiring board, a frame, and a cover, comprising:
mounting the printed wiring board to the frame;
locating the cover with respect to the frame by way of a first pin and a second pin; and
fastening the cover to the frame.

23. The method of claim 22, wherein the printed wiring board assembly further includes a mezzanine board, further comprising:
locating the mezzanine board with respect to the cover by way of a third pin and a fourth pin.

24. The method of claim 23, further comprising:
fastening the mezzanine board to the cover.

25. The method of claim 23, wherein the printed wiring board assembly further includes a first connector half coupled to the mezzanine board and a second connector half coupled to the printed wiring board, further comprising:
aligning the first connector half with the second connector half by way of the first pin, the second pin, the third pin, and the fourth pin; and
mating the first connector half with the second connector half to make an electrical connection between the mezzanine board and the printed wiring board.

26. The method of claim 24, wherein the printed wiring board assembly further includes a first connector half coupled to the mezzanine board, further comprising:
fastening the mezzanine board to a top surface of the cover; and
placing the first connector half through an aperture in the cover.

27. The method of claim 24, further comprising:
fastening the mezzanine board to a bottom surface of the cover.

28. The method of claim 22, further comprising:
creating a cavity defined by the frame and the cover;
placing the printed wiring board in the cavity.

29. The method of claim 22, further comprising:
transferring heat away from the printed wiring board by way of the frame.

30. The method of claim 23, further comprising:
transferring heat away from the mezzanine board by way of the cover.

31. The method of claim 23, further comprising:
preventing vertical movement of the mezzanine board with respect to the cover by way of the third pin and the fourth pin.
